(19) United States
(12) Patent Application Publication
(10) Pub. No.: US 2025/0227918 A1
(43) Pub. Date: Jul. 10, 2025

(54) SEMICONDUCTOR DEVICES HAVING SPACER STRUCTURES

(71) Applicant: Samsung Electronics Co., Ltd., Suwon-si (KR)

(72) Inventors: Seojin Ahn, Suwon-si (KR); Yoongoo Kang, Suwon-si (KR); Changwoo Seo, Suwon-si (KR); Dongyoung Kim, Suwon-si (KR); Cheolho Kim, Suwon-si (KR); Seokjae Won, Suwon-si (KR); Jaehong Park, Suwon-si (KR)

(21) Appl. No.: 18/912,799

(22) Filed: Oct. 11, 2024

(30) Foreign Application Priority Data
Jan. 9, 2024 (KR) 10-2024-0003239

(51) Int. Cl. H10B 12/00; H01L 29/49

(52) U.S. Cl. CPC H10B 12/485; H10B 12/315; H10B 12/482; H10D 64/666

(57) ABSTRACT

A semiconductor device includes a substrate that includes an active region including first and second impurity regions, the substrate further including a contact hole that overlaps an upper surface of the first impurity region; a gate structure in the substrate and intersecting the active region; a bit line structure intersecting the gate structure, the bit line structure including a bit line contact and a bit line on the bit line contact; a spacer structure including an internal spacer on a side surface of the bit line structure and an external spacer on the internal spacer; and a contact plug in contact with a first side surface of the external spacer and electrically connected to the second impurity region. The internal spacer includes a first spacer in contact with a second side surface of the external spacer. The first spacer includes a different material from the external spacer.

### CROSS-REFERENCE TO RELATED APPLICATIONS

This application claims benefit of priority to Korean Patent Application No. 10-2024-0003239 filed on Jan. 9, 2024, in the Korean Intellectual Property Office, the disclosure of which is incorporated herein by reference in its entirety.

### BACKGROUND OF THE INVENTION

The present disclosure relates to semiconductor devices having spacer structures.

As demand for high performance, high speed, and/or multifunctionality of semiconductor devices increases, the degree of integration of semiconductor devices is also increasing. When manufacturing finely-patterned semiconductor devices in response to the trend of high integration of semiconductor devices, it may be helpful to implement patterns with a fine width or a fine spacing distance.

### SUMMARY OF THE INVENTION

Aspects of the present disclosure may provide a semiconductor device including a landing pad structure in which an upper landing pad is integrally coupled to a metal layer of a lower landing pad.

Aspects of the present disclosure may provide a semiconductor device including a landing pad structure in which a landing pad structure is integrally coupled to a contact plug.

According to some aspects of the present disclosure, a semiconductor device may include: a substrate that includes an active region including a first impurity region and a second impurity region, the substrate further including a contact hole that overlaps an upper surface of the first impurity region; a gate structure in the substrate and intersecting the active region; a bit line structure intersecting the gate structure, the bit line structure including a bit line contact in the contact hole and in contact with the first impurity region and a bit line on the bit line contact; a spacer structure including an internal spacer on a side surface of the bit line structure and an external spacer on the internal spacer; and a contact plug in contact with a first side surface of the external spacer and electrically connected to the second impurity region. The internal spacer may be in the contact hole and may include a first spacer in contact with a second side surface of the external spacer opposite to the first side surface. The first spacer may include a different material from the external spacer.

According to some aspects of the present disclosure, a semiconductor device may include: a substrate that includes an active region including a first impurity region and a second impurity region, the substrate further including a contact hole that vertically overlaps an upper surface of the first impurity region; a gate structure in the substrate and intersecting the active region; a buffer layer on the substrate; a bit line structure intersecting the gate structure, the bit line structure including a bit line contact in the contact hole and in contact with the first impurity region and a bit line on the bit line contact; a spacer structure including an internal spacer on a side surface of the bit line structure and an external spacer on the internal spacer; and a contact plug in contact with a first side surface of the external spacer and electrically connected to the second impurity region. The internal spacer may be in the contact hole and may include a first spacer in contact with a second side surface of the external spacer opposite to the first side surface. The first spacer may include a first portion that is closer to a lower surface of the substrate than a lower surface of the buffer layer is, and a second portion that horizontally overlaps the buffer layer. A maximum horizontal width of the first portion of the first spacer may be wider than a horizontal width of the second portion of the first spacer.

According to some aspects of the present disclosure, a semiconductor device may include: a substrate that includes an active region including a first impurity region and a second impurity region, the substrate further including a contact hole that overlaps the first impurity region and a recess region that overlaps the second impurity region; a gate structure in the substrate and intersecting the active region; bit line structures intersecting the gate structure, at least one of the bit line structures including a bit line contact in the contact hole and in contact with the first impurity region and a bit line on the bit line contact; spacer structures each including an internal spacer on a side surface of a respective one of the bit line structures and an external spacer on the internal spacer; a contact plug between ones of the spacer structures and electrically connected to the second impurity region; a landing pad on the contact plug; and a capacitor structure on the landing pad. The internal spacer may be in the contact hole and may include a first spacer in contact with a side surface of the external spacer. The external spacer may include silicon nitride, and the first spacer may include at least one of silicon oxycarbide or silicon oxycarbonitride.

According to some embodiments of the present disclosure, an internal spacer of a spacer structure may include a material having a lower tensile stress than a material included in an external spacer. Accordingly, bending of the bit line structure may be prevented.

Advantages and effects of the present application are not limited to the foregoing content and may be more easily understood in the process of describing specific example embodiments of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a plan view of a semiconductor device according to some example embodiments;

FIG. 2 is a vertical cross-sectional view taken along lines I-I′ and II-II′ of the semiconductor device illustrated in FIG. 1;

FIG. 3 is a partially enlarged view of the semiconductor device illustrated in FIG. 2;

FIGS. 4 to 7 are vertical cross-sectional views of a semiconductor device according to some example embodiments;

FIGS. 8 to 18 are vertical cross-sectional views illustrating a method of manufacturing a semiconductor device according to some example embodiments; and

FIGS. 19 to 21 are vertical cross-sectional views illustrating a method of manufacturing a semiconductor device according to some example embodiments.

### DETAILED DESCRIPTION

Hereinafter, example embodiments of the present disclosure will be described with reference to the accompanying drawings.

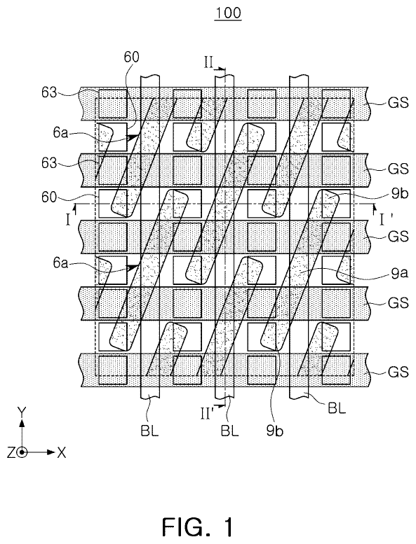

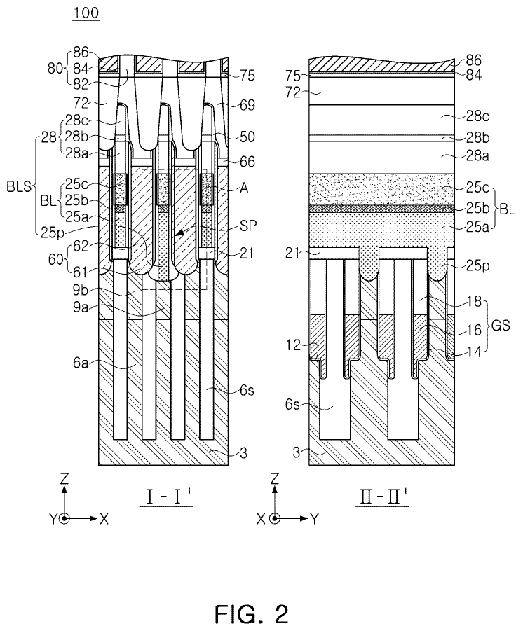

FIG. 1 is a plan view of a semiconductor device according to some example embodiments. FIG. 2 is a vertical cross-sectional view taken along lines I-I′ and II-II′ of the semiconductor device illustrated in FIG. 1.

Referring to FIGS. 1 and 2, a semiconductor device 100 according to some example embodiments of the present disclosure includes a substrate 3, a gate structure GS, a buffer layer 21, a bit line structure BLS, a spacer structure SP, a contact plug 60, a landing pad 69, an insulating pattern 72, and a capacitor structure 80. The semiconductor device 100 may be applied to, for example, a cell array of Dynamic Random Access Memory (DRAM), but the present disclosure is not limited thereto.

The substrate 3 may include a semiconductor material, such as a group IV semiconductor, a group III-V compound semiconductor, or a group II-VI compound semiconductor. For example, the group IV semiconductor may include silicon, germanium, or silicon-germanium. The substrate 3 may be a silicon substrate, a silicon on insulator (SOI) substrate, a germanium substrate, a germanium on insulator (GOI) substrate, a silicon-germanium substrate, or a substrate including an epitaxial layer.

The substrate 3 may include an active region 6a, a device isolation layer 6s, a first impurity region 9a, and a second impurity region 9b. The device isolation layer 6s may be an insulating layer extending downwardly from an upper surface of the substrate 3 and may define the active region 6a. For example, the active region 6a may correspond to a portion of the upper surface of the substrate 3 surrounded by the device isolation layer 6s. In a plan view, the active region 6a may have a bar shape with a minor axis and a major axis and may extend in a direction inclined (i.e., diagonal) to an X-direction and a Y-direction. For example, the X-direction and the Y-direction may intersect each other and may be parallel to a lower surface of the substrate 3. It will be understood that “an element A surrounds an element B” (or similar language) as used herein means that the element A is at least partially around the element B but does not necessarily mean that the element A completely encloses the element B.

The active region 6a may include first and second impurity regions 9a and 9b extending from the upper surface of the substrate 3 by a predetermined depth. The first and second impurity regions 9a and 9b may be spaced apart from each other. The first and second impurity regions 9a and 9b may be provided as source/drain regions of a transistor. For example, for one active region 6a, two gate structures GS may cross the one active region 6a, the drain region may be formed between the two gate structures GS, and the source regions may be formed in regions opposite to the drain region for the two gate structures GS. For example, the first impurity region 9a may correspond to the drain region, and the second impurity region 9b may correspond to the source region, but the present disclosure is not limited thereto. The source region and the drain region are formed by first and second impurity regions 9a and 9b by doping or ion implantation of substantially the same impurities, and may be referred to interchangeably depending on the circuit configuration of a transistor that is ultimately formed. The first and second impurity regions 9a and 9b may include impurities having a conductivity type opposite to that of the substrate 3. For example, the active regions 6a may include P-type impurities, and the first and second impurity regions 9a and 9b may include N-type impurities.

The device isolation layer 6s may extend downwardly from the upper surface of the substrate 3 and may define active regions 6a. The device isolation layer 6s may surround the active regions 6a and separate the active regions 6a from each other. The device isolation layer 6s may include silicon oxide, silicon nitride, silicon oxynitride, or a combination thereof, and may be formed of a single layer or multiple layers.

In a plan view, the gate structures GS may extend in the X-direction and may be spaced apart from each other in the Y-direction. The transistors including the gate structure GS and the first and second impurity regions 9a and 9b, respectively, may form a buried channel array transistor (BCAT), but the present disclosure is not limited thereto.

In a cross-sectional view, the gate structures GS may be buried in the substrate 3, for example, the gate structures GS may be disposed inside a gate trench 12 formed in the substrate 3. The gate structure GS may include a gate dielectric layer 14, a gate electrode 16, and a gate capping layer 18, disposed in the gate trench 12. The gate dielectric layer 14 may be formed conformally on an internal wall of the gate trench 12. The gate electrode 16 may be disposed in a lower portion of the gate trench 12, and the gate capping layer 18 may be disposed on an upper portion of the gate structure GS and may fill the gate trench 12. A portion of an upper surface of the gate capping layer 18 may be coplanar with an upper surface of the device isolation layer 6s.

The gate dielectric layer 14 may include silicon oxide or a material having a high dielectric constant. In some example embodiments, the gate dielectric layer 14 may be a layer formed by oxidizing the active region 6a, or may be a layer formed by deposition. The gate electrode 16 may include a conductive material, for example, at least one of polycrystalline silicon (Si), titanium (Ti), titanium nitride (TiN), tantalum (Ta), tantalum nitride (TaN), tungsten (W), tungsten nitride (WN), or aluminum (Al). The gate capping layer 18 may include silicon nitride.

The buffer layer 21 may be disposed on the active region 6a, the device isolation layer 6s, and the gate structure GS. The buffer layer 21 may include silicon oxide, silicon nitride, silicon oxynitride, or a combination thereof. The buffer layer 21 may be formed of a single layer or multiple layers.

The bit line structures BLS may extend in the Y-direction and may be spaced apart from each other in the X-direction. The bit line structure BLS may have a bar shape extending in the Y-direction. The bit line structure BLS may include a bit line contact 25p, a bit line BL on the bit line contact 25p, and a bit line capping layer 28 on the bit line BL. The bit line BL may include a first conductive layer 25a, a second conductive layer 25b, and a third conductive layer 25c sequentially stacked on the buffer layer 21. The second conductive layer 25b may be between the first conductive layer 25a and the third conductive layer 25c. The first conductive layer 25a may include polysilicon. The second conductive layer 25b may include a metal-semiconductor compound. For example, the metal-semiconductor compound may be a layer in which a portion of the first conductive layer 25a is converted into silicide. For example, the metal-semiconductor compound may include cobalt silicide (CoSi), titanium silicide (TiSi), nickel silicide (NiSi), tungsten silicide (WSi), or other metal silicides, or may include nitrides such as TiSiN. The third conductive layer 25c may include a metallic material such as titanium (Ti), tantalum (Ta), tungsten (W), and aluminum (Al).

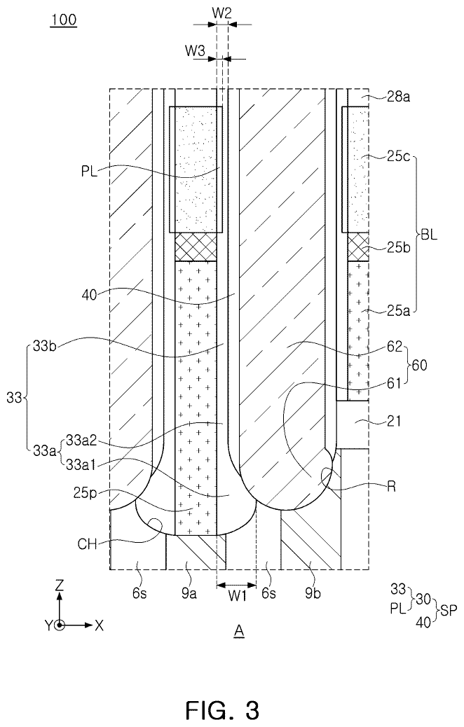

The bit line contact 25p may be disposed below the bit line BL and may be electrically connected to the active region 6a. For example, the bit line contact 25p may be disposed below the first conductive layer 25a and may extend downwardly, and may be in contact with the first impurity region 9a. The bit line contact 25p may be disposed in a contact hole CH (e.g., see FIG. 3) formed on the upper surface of the substrate 3. For example, the substrate 3 may include the contact hole CH, and the contact hole CH may vertically overlap an upper surface of the first impurity region 9a (e.g., in the Z-direction). The bit line contact 25p may electrically connect the active region 6a to the bit line structure BLS. The bit line contact 25p may include the same material as the first conductive layer 25a, and may be formed integrally with the first conductive layer 25a. For example, a conductive material disposed below the second conductive layer 25b and disposed on a level higher than that of an upper surface of the buffer layer 21 may be referred to as the first conductive layer 25a, and a conductive material disposed on a level lower than that of the upper surface of the buffer layer 21 and in contact with the first impurity region 9a may be referred to as the bit line contact 25p. As used herein, the term “level” refers to a height or distance in a Z-direction (e.g., vertical direction) from a lower surface of the substrate 3. For example, the Z-direction may intersect the X-direction and the Y-direction and may be perpendicular to the lower surface of the substrate 3.

The bit line capping layer 28 may include a first insulating layer 28a, a second insulating layer 28b, and a third insulating layer 28c disposed on the bit line BL. A side surface of the first insulating layer 28a may be coplanar with a side surface of the first conductive layer 25a, the second conductive layer 25b, and the third conductive layer 25c. The first insulating layer 28a, the second insulating layer 28b, and the third insulating layer 28c may include silicon oxide, silicon nitride, silicon oxynitride, or a combination thereof.

FIG. 3 is a partially enlarged view of the semiconductor device illustrated in FIG. 2. Specifically, FIG. 3 corresponds to region A of FIG. 2.

Referring to FIGS. 2 and 3, spacer structures SP may be disposed on both side surfaces (i.e., opposing side surfaces) of a bit line structures BLS and may extend in the Y-direction along the side surfaces of the bit line structures BLS. The spacer structure SP may include an internal spacer 30 in contact with the side surfaces of the bit line structures BLS and an external spacer 40 on (e.g., covering) the internal spacer 30. In some example embodiments, upper ends of the internal spacer 30 and the external spacer 40 may be disposed on a level lower than upper ends of the bit line structures BLS.

The internal spacer 30 may include a first spacer 33 and a protective layer PL. The first spacer 33 may be on (e.g., may cover) a side surface of the bit line contact 25p and may fill a contact hole CH. For example, the first spacer 33 may be in contact with an internal wall of the contact hole CH and may be in partial contact with a device isolation layer 6s and a first impurity region 9a. The first spacer 33 may extend in a horizontal direction along the side surface of the bit line structure BLS and may surround the bit line structure BLS.

In some example embodiments, the first spacer 33 may extend vertically and be on (e.g., cover) a portion of a side surface of a bit line BL and a side surface of a bit line capping layer 28. For example, a portion of the first spacer 33 in contact with the side surface of the bit line contact 25p in the contact hole CH may be referred to as a lower portion 33a, and a portion of the first spacer 33 in contact with the side surface of the bit line BL and the side surface of the bit line capping layer 28 on the lower portion 33a may be referred to as an upper portion 33b. A maximum horizontal width W1 of the lower portion 33a of the first spacer 33 may be wider than a horizontal width W2 of the upper portion 33b of the first spacer 33. The first spacer 33 may include a first portion 33al and a second portion 33a2. For example, a portion of the lower portion 33a disposed below a lower surface of a buffer layer 21 may be referred to as the first portion 33a1, and a portion of the lower portion 33a that overlaps the buffer layer 21 in the horizontal direction (e.g., the X-direction) may be referred to as the second portion 33a2. For example, the first portion 33al may be closer to a lower surface of the substrate 3 than the lower surface of the buffer layer 21 is. As used herein, “an element A overlaps an element B in a direction” (or similar language) means that there is at least one straight line that extends in the direction and intersects both the elements A and B.

The protective layer PL may be on (e.g., may cover) a portion of the side of the bit line BL. For example, the protective layer PL may be in contact with a side surface of a third conductive layer 25c. A horizontal width W3 of the protective layer PL may be smaller than a horizontal width of the lower portion 33a and the upper portion 33b of the first spacer 33. The first spacer 33 may be on (e.g., may cover) the protective layer PL. For example, a portion of the upper portion 33b that overlaps the protective layer PL in the horizontal direction (e.g., the X-direction) may be referred to as a first portion, and a portion of the upper portion 33b that does not overlap the protective layer PL in the horizontal direction and overlaps the protective layer PL in a vertical direction (e.g., the Z-direction) may be referred to as a second portion. For example, the first portion of the upper portion 33b may be spaced apart from a side surface of the bit line BL (e.g., a side surface of the third conductive layer 25c), with the protective layer PL therebetween. A horizontal width of the first portion may be smaller than a horizontal width W2 of the second portion. In FIG. 3, an upper end and a lower end of the protective layer PL are illustrated as being disposed on the same level as an upper surface and a lower surface of the third conductive layer 25c, respectively, but the present disclosure is not limited thereto. In some example embodiments, at least one of the upper end or the lower end of the protective layer PL may be disposed on a different level from the upper surface or the lower surface, respectively, of the third conductive layer 25c.

The external spacer 40 may be on (e.g., may cover) a side surface of the first spacer 33. For example, the external spacer 40 may be on (e.g., may cover) a side surface of the upper portion 33b of the first spacer 33. The external spacer 40 may be disposed on the first portion 33al of the lower portion 33a of the first spacer 33 and may be in contact with a side surface of the second portion 33a2 of the lower portion 33a. A portion of the external spacer 40 may be disposed in the contact hole CH, but may not completely cover the lower portion 33a of the first spacer 33. A lower end of the external spacer 40 may be disposed on a level higher than that of a lower end of the lower portion 33a and may be disposed on a level lower than that of an upper surface of the substrate 3. For example, a lower end of the external spacer 40 may be closer to a lower surface of the substrate 3 than an upper surface of the substrate 3 is.

The first spacer 33 may include a different material from the external spacer 40. In some example embodiments, the first spacer 33 may include a material having a lower tensile stress than a material included in the external spacer 40. For example, the first spacer 33 may include at least one of silicon oxycarbide (SiOC) or silicon oxycarbonitride (SiOCN). The external spacer 40 may include silicon nitride. The protective layer PL may include at least one of silicon or silicon oxide.

The internal spacer 30 of the spacer structure SP may include a first spacer 33, and the first spacer 33 may include a material having a lower tensile stress than a material included in the external spacer 40. Accordingly, during a semiconductor device manufacturing process, bending of the bit line structure BLS may be prevented or reduced.

A contact plug 60 may be disposed between the bit line structures BLS and may be in contact with the spacer structures SP. When viewed in a plan view, the contact plugs 60 may be disposed between the bit line structures BLS and between the gate structures GS. For example, the contact plug 60 may be between ones of the spacer structures SP.

A lower end of the contact plug 60 may be disposed on a level lower than that of the upper surface of the substrate 3, and the upper surface of the contact plug 60 may be disposed on a level lower than an upper end of the bit line structure BLS. For example, the substrate 3 may include a recess region R on an upper surface thereof, and a portion of the contact plug 60 in (e.g., filling) the recess region R may be referred to as a lower portion 61. For example, the recess region R may vertically overlap an upper surface of a second impurity region 9b. The lower portion 61 may be in contact with a device isolation layer 6s, a second impurity region 9b, and the first spacer 33. A portion of the contact plug 60 disposed on the lower portion 61 and in contact with the bit line structures BLS and/or spacer structure SP may be referred to as an upper portion 62. For example, the upper portion 62 of the contact plug 60 may be in contact with the external spacer 40. The lower portion 61 of the contact plug 60 may be in contact with the first portion 33al of the lower portion 33a of the first spacer 33. The second portion 33a2 of the lower portion 33a of the first spacer 33 may be spaced apart from the contact plug 60 (e.g., with the external spacer 40 therebetween). The contact plug 60 may be electrically connected to the second impurity region 9b.

The contact plug 60 may be formed of a conductive material, for example, at least one of polysilicon (Si), titanium (Ti), titanium nitride (TiN), tantalum (Ta), tantalum nitride (TaN), tungsten (W), tungsten nitride (WN) or aluminum (Al). In some example embodiments, the contact plug 60 may include doped polysilicon and may include N-type impurities such as phosphorus (P), arsenic (As), and antimony (Sb).

The semiconductor device 100 may further include a fence structure 63 disposed between the bit line structures BLS (e.g., see FIG. 1). The fence structures 63 may overlap the gate structures GS in a vertical direction (e.g., the Z-direction) and may be alternately arranged with the contact plugs 60 in the Y-direction. The fence structures 63 may spatially separate the contact plugs 60 from each other and may electrically insulate the contact plugs 60 from each other. The fence structure 63 may have a rod shape or a pillar shape extending in the vertical direction. Although not illustrated, a lower surface of the fence structure 63 may be in contact with a gate capping layer 18 of the gate structure GS. The fence structure 63 may include an insulating material, for example, silicon nitride.

The semiconductor device 100 may further include a metal-semiconductor compound layer 66 disposed on an upper surface of the contact plug 60. The metal-semiconductor compound layer 66 may be in contact with a side surface of the spacer structure SP. The metal-semiconductor compound layer 66 may be formed by converting a portion of the contact plug 60 including polysilicon, into silicide. The metal-semiconductor compound layer 66 may include cobalt silicide (CoSi), titanium silicide (TiSi), nickel silicide (NiSi), tungsten silicide (WSi), or other metal silicides.

In some example embodiments, the semiconductor device 100 may further include an upper insulating spacer 50 on (e.g., partially covering) the bit line capping layer 28 and the spacer structure SP. The upper insulating spacer 50 may extend along the bit line capping layer 28 and the spacer structure SP and may be in contact with an upper surface of the metal-semiconductor compound layer 66.

A landing pad 69 may be disposed on the metal-semiconductor compound layer 66 and may be on (e.g., may cover) the upper insulating spacer 50. The landing pad 69 may be electrically connected to the second impurity region 9b of the active region 6a through the contact plug 60. For example, the landing pad 69 may be on the contact plug 60. The landing pad 69 may include a barrier layer and a metal layer on the barrier layer. The barrier layer may include at least one of metal nitrides, such as titanium nitride (TiN), tantalum nitride (TaN), or tungsten nitride (WN). The metal layer may include at least one of conductive materials, such as titanium (Ti), tantalum (Ta), tungsten (W), molybdenum (Mo), or aluminum (Al).

The insulating pattern 72 may be disposed between the landing pads 69. The insulating pattern 72 may spatially separate the landing pads 69 from each other, and may electrically isolate the landing pads 69 from each other. The insulating pattern 72 may include silicon oxide, silicon nitride, silicon oxynitride, or a combination thereof. For example, the insulating pattern 72 may include silicon nitride.

The semiconductor device 100 may further include an etch stop layer 75 on (e.g., covering) upper surfaces of the landing pad 69 and the insulating pattern 72. The capacitor structure 80 may be disposed on the landing pad 69 and the insulating pattern 72. The capacitor structure 80 may include a lower electrode 82, a capacitor dielectric layer 84, and an upper electrode 86. The lower electrode 82 may penetrate through (i.e., extend through) the etch stop layer 75 to come into contact with an upper surface of the landing pad 69. The capacitor dielectric layer 84 may be on (e.g., may cover) the lower electrode 82 and the etch stop layer 75, and the upper electrode 86 may be on (e.g., may cover) the capacitor dielectric layer 84. The capacitor structure 80 may be electrically connected to the landing pad 69 and the contact plug 60. The lower electrode 82 and the upper electrode 86 may include at least one of a doped semiconductor, metal nitride, a metal, or metal oxide. The lower electrode 82 and the upper electrode 86 may include, for example, at least one of polycrystalline silicon, titanium nitride (TiN), tungsten (W), titanium (Ti), ruthenium (Ru), or tungsten nitride (WN). For example, the capacitor dielectric layer 84 may include at least one of high dielectric constant materials, such as zirconium oxide (ZrO₂), aluminum oxide (Al₂O₃), or hafnium oxide (Hf₂O₃).

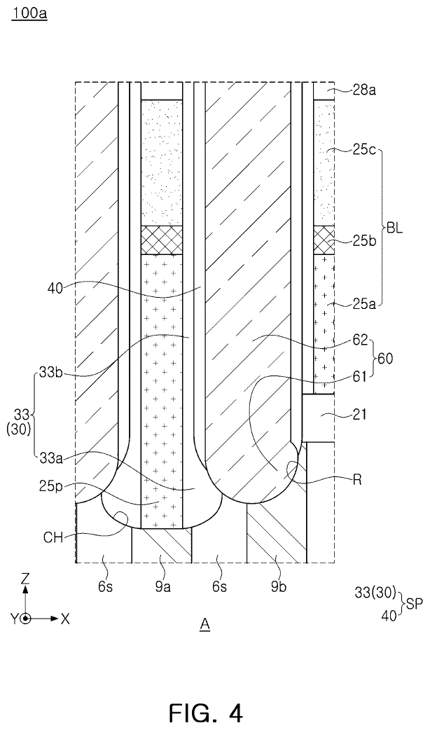

FIGS. 4 to 7 are vertical cross-sectional views of a semiconductor device according to some example embodiments. For conciseness, an element previously described with reference to FIGS. 1 to 3 may be identified by the same reference number and a description thereof may be brief or omitted to avoid repeated descriptions.

Referring to FIG. 4, a spacer structure SP of a semiconductor device 100a may include an internal spacer 30 and an external spacer 40. In some example embodiments, a protective layer PL may be omitted from the internal spacer 30. For example, the first spacer 33 may form the internal spacer 30, and may be in contact with a first conductive layer 25a, a second conductive layer 25b, and a third conductive layer 25c of a bit line BL.

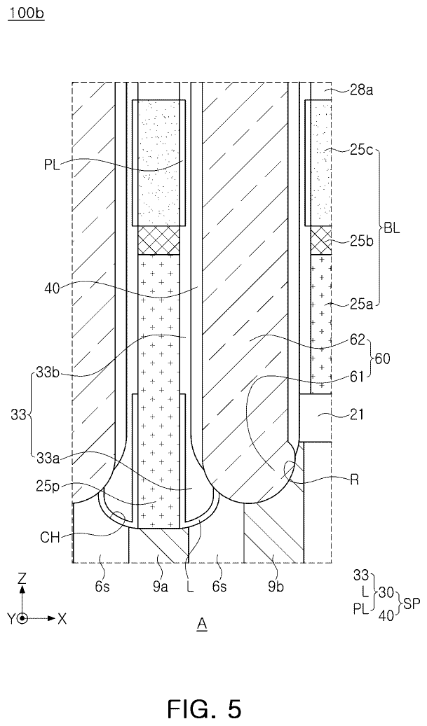

Referring to FIG. 5, a spacer structure SP of a semiconductor device 100b may include an internal spacer 30 and an external spacer 40. In some example embodiments, the internal spacer 30 may further include a liner L. The liner L may be in contact with a side surface of the bit line contact 25p and an internal wall of a contact hole CH. For example, the liner L may extend conformally along the side surface of the bit line contact 25p and the internal wall of the contact hole CH. The first spacer 33 may be disposed on the liner L and may fill the contact hole CH. For example, the liner L may be between the first spacer 33 and the substrate 3. The liner L may include a material different from that of the external spacer 40, for example, silicon oxide. Since the liner L includes silicon oxide, this may prevent depletion regions from being formed on side surfaces of the bit line contact 25p and the first conductive layer 25a. Accordingly, the electrical characteristics of the bit line contact 25p and the first conductive layer 25a may be prevented from being deteriorated.

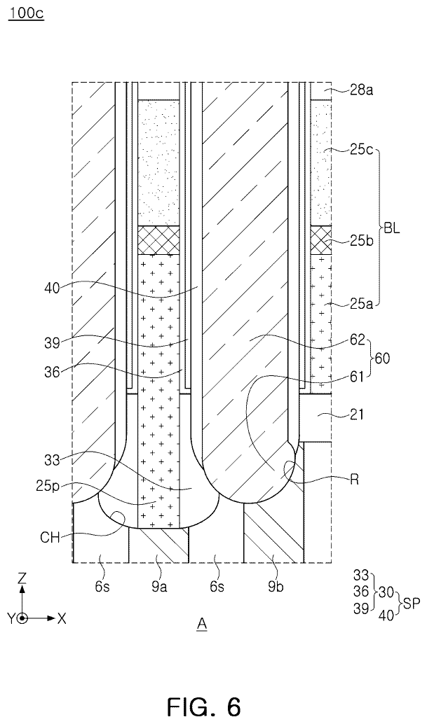

Referring to FIG. 6, a spacer structure SP of a semiconductor device 100c may include an internal spacer 30 and an external spacer 40. In some example embodiments, the internal spacer 30 may include a second spacer 36 and a third spacer 39 on the first spacer 33. For example, the first spacer 33 may fill the contact hole CH, and an upper surface of the first spacer 33 may be lower than or coplanar with an upper surface of the buffer layer 21. The second spacer 36 may be in contact with a side surface of the bit line structure BLS and an upper surface of the first spacer 33, and may be conformally disposed along the side surface of the bit line structure BLS and the upper surface of the first spacer 33. The third spacer 39 may be disposed on the second spacer 36 and may be disposed between the second spacer 36 and the external spacer 40. Unlike the semiconductor device 100 illustrated in FIG. 3, the protective layer PL may be omitted in the semiconductor device 100c.

The second spacer 36 and the third spacer 39 may include silicon oxide, silicon nitride, silicon oxynitride, or a combination thereof. For example, the second spacer 36 may include silicon nitride, and the third spacer 39 may include silicon oxide.

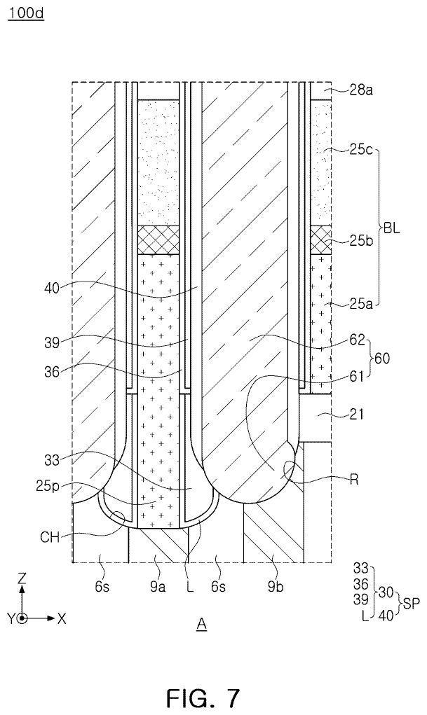

Referring to FIG. 7, a spacer structure SP of a semiconductor device 100d may include an internal spacer 30 and an external spacer 40. In some example embodiments, the internal spacer 30 may include a liner L, a first spacer 33, a second spacer 36, and a third spacer 39. The liner L and the first spacer 33 may fill the contact hole CH. An upper end of the liner L may be in contact with the second spacer 36. A width of the liner L (e.g., in the X-direction) is illustrated as being the same as a width of the second spacer 36, but the present disclosure is not limited thereto.

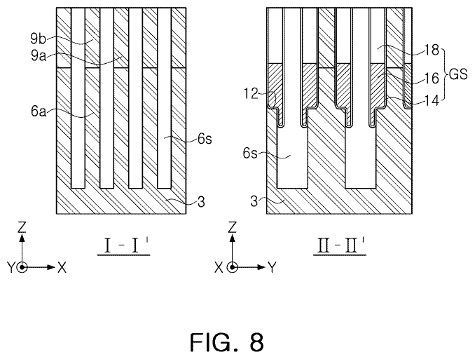

FIGS. 8 to 18 are vertical cross-sectional views illustrating a method of manufacturing a semiconductor device according to some example embodiments. Specifically, FIGS. 8 to 18 correspond to vertical cross-sectional views taken along line I-I′ and line II-II′ of FIG. 1.

Referring to FIG. 8, a device isolation layer 6s and a gate structure GS may be formed in a substrate 3. The device isolation layer 6s may be formed by forming a trench on an upper surface of the substrate 3, filling the trench with an insulating material, and performing a planarization process to etch the substrate 3 and the insulating material. The device isolation layer 6s may define active regions 6a. For example, the active regions 6a may correspond to a portion of the upper surface of the substrate 3 surrounded by the device isolation layer 6s. In a plan view, the active regions 6a may have a bar shape with a minor axis and a major axis and may be spaced apart from each other. The device isolation layer 6s may be formed of a single layer or multiple layers.

In some example embodiments, impurity regions may be formed by injecting impurities into the substrate 3 before the device isolation layer 6s is formed. In other example embodiments, the impurity regions may be formed after forming the device isolation layer 6s or in another process operation.

Then, gate trenches 12 may be formed by anisotropically etching the substrate 3. The gate trenches 12 may extend in the X-direction, and may cross the active region 6a and the device isolation layer 6s. A gate structure GS may be formed by forming a gate dielectric layer 14, a gate electrode 16, and a gate capping layer 18 in the gate trench 12. The gate dielectric layer 14 may be formed conformally on an internal wall of the gate trench 12. The gate electrode 16 may be formed by forming a conductive material on the gate dielectric layer 14 and then recessing the conductive material. The gate capping layer 18 may be formed by forming an insulating material on the gate electrode 16 to fill the gate trench 12 and then performing a planarization process. In some example embodiments, as illustrated in FIG. 8, the gate trench 12 may be formed to be deeper in the device isolation layer 6s than in the active region 6a.

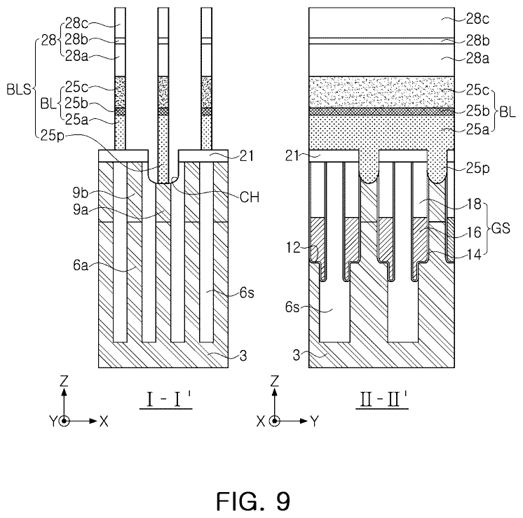

Referring to FIG. 9, a buffer layer 21 and a bit line structure BLS may be formed on the substrate 3. The buffer layer 21 may be formed on upper surfaces of the substrate 3, the active region 6a, the device isolation layer 6s, and the gate structure GS. The buffer layer 21 may be formed of a single layer or multiple layers.

The bit line structure BLS may be formed on the substrate 3 and the buffer layer 21. The bit line structure BLS may be formed by forming a contact hole CH by etching the buffer layer 21 to expose a first impurity region 9a of the active region 6a, stacking conductive material layers on the contact hole CH and the buffer layer 21, forming insulating material layers on the conductive material layers, and patterning the conductive material layers and the insulating material layers. For example, the patterned conductive material layers and insulating material layers may extend in the Y-direction and may form a bit line structure BLS. An internal wall of the contact hole CH may be partially exposed through the patterning process. The bit line structures BLS may extend in the Y-direction and may be spaced apart from each other in the X-direction.

The bit line structure BLS may include a bit line contact 25p including a conductive material, a bit line BL, and a bit line capping layer 28 including an insulating material. The bit line BL may include a first conductive layer 25a, a second conductive layer 25b, and a third conductive layer 25c, which are sequentially stacked, and the first conductive layer 25a may be disposed on the bit line contact 25p disposed in the contact hole CH. The bit line capping layer 28 may include a first insulating layer 28a, a second insulating layer 28b, and a third insulating layer 28c, which are sequentially stacked.

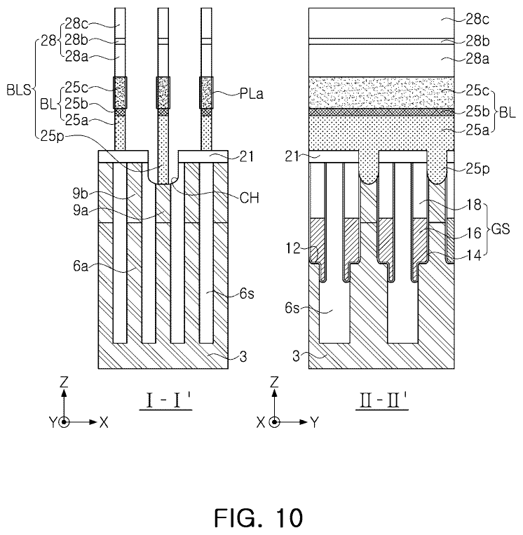

Referring to FIG. 10, a protective material layer PLa may be formed on a side surface of the bit line BL. The protective material layer PLa may be selectively deposited on a side surface of the third conductive layer 25c and may include silicon. For example, a silicon precursor such as DIPAS (Diisopropylaminosilane) and disilane may be supplied on a resulting structure of FIG. 9 and a heating process may be performed. The precursor may react with polysilicon at about 400° C. to about 500° C. to deposit a silicon thin film on polysilicon. According to some example embodiments of the present disclosure, the protective material layer PLa may be selectively deposited on the side surface of the third conductive layer 25c including a metal such as tungsten (W) by performing a heating process at a temperature lower than about 400° C.

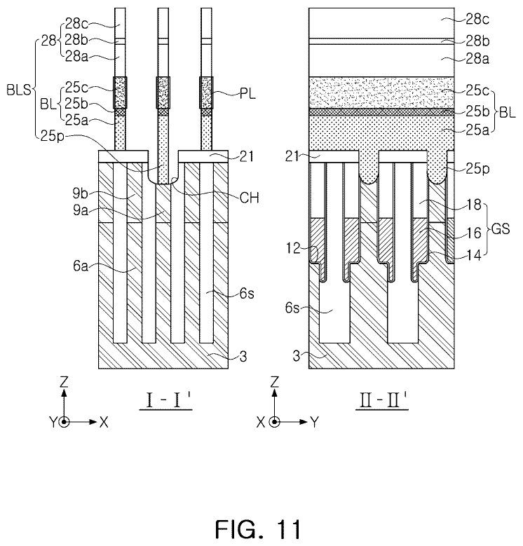

Referring to FIG. 11, an annealing process may be performed, and the protective material layer PLa may react with the third conductive layer 25c to form a protective layer PL. After the patterning process described with reference to FIG. 9, the third conductive layer 25c may be naturally oxidized to form a metal oxide such as tungsten oxide on the side surface of the third conductive layer 25c. However, after covering the third conductive layer 25c with the protective material layer PLa, the annealing process may be performed, and oxygen atoms of the metal oxide layer may move to the protective material layer PLa. Silicon in the protective material layer PLa may react with oxygen atoms to form silicon oxide. For example, all or part of the protective layer PL may be formed of silicon oxide, and the protective layer PL may include at least one of silicon or silicon oxide. In this manner, since the protective layer PL is formed on the third conductive layer 25c by performing the annealing process, it may be possible to prevent the third conductive layer 25c from being oxidized by an oxide of a first spacer 33 described below. Accordingly, the electrical characteristics of the bit line BL may be prevented from being deteriorated.

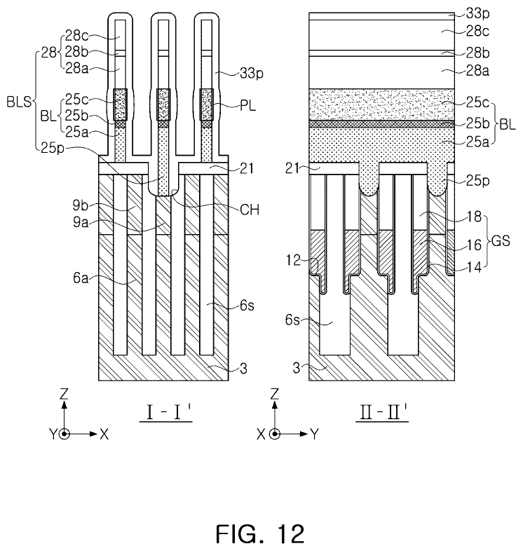

Referring to FIG. 12, a first spacer material layer 33p may be formed. The first spacer material layer 33p may be on (e.g., may cover) the buffer layer 21, the bit line structure BLS, and the bit line contact 25p, and may fill the contact hole CH. The first spacer material layer 33p may include at least one of SiOC or SiOCN.

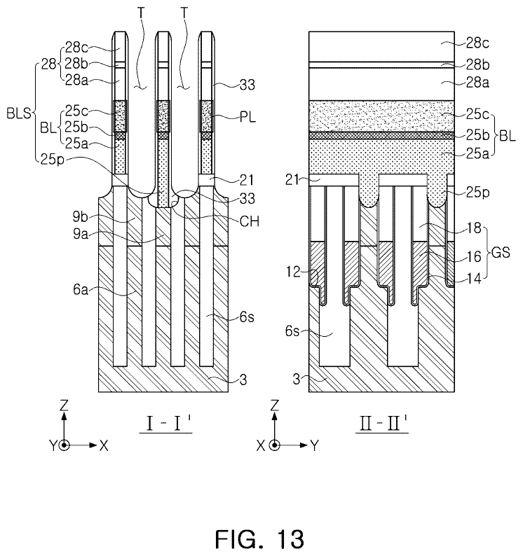

Referring to FIG. 13, an anisotropic etching process may be performed, and the first spacer material layer 33p may be etched to form a first spacer 33. For example, an etching process may be performed to form trenches T extending in the Y-direction between the bit line structures BLS. The trench T may expose a side surface of the buffer layer 21, a second impurity region 9b, and an upper surface of the device isolation layer 6s. A lower end of the trench T may be disposed on a level lower than that of an upper end of the substrate 3. Through the etching process, a thickness (i.e., width) of the first spacer material layer 33p may be reduced, and the first spacer 33 may be formed. The first spacer 33 may be on (e.g., may cover) a side surface of the bit line structure BLS and fill the contact hole CH. The first spacer 33 may extend in the Y-direction along the side surface of the bit line structure BLS. Additionally, an upper surface of the third insulating layer 28c may be exposed through the etching process.

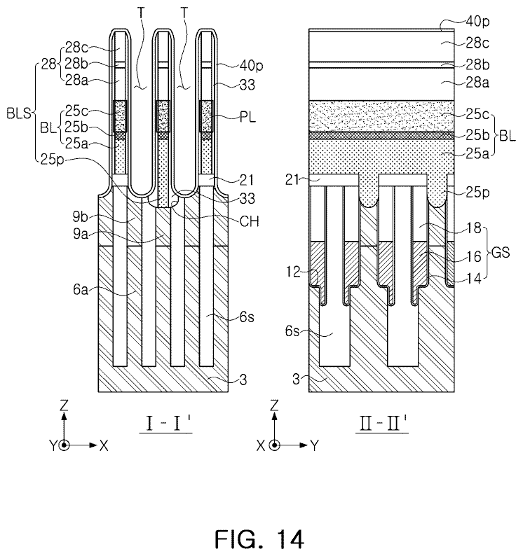

Referring to FIG. 14, a spacer material layer 40p may be formed. The spacer material layer 40p may be on (e.g., may cover) an internal wall of the trench T. For example, the spacer material layer 40p may be on (e.g., may cover) the side surface of the buffer layer 21, the second impurity region 9b, and the upper surface of the device isolation layer 6s, and may be on (e.g., may cover) the first spacer 33. The spacer material layer 40p may include silicon nitride.

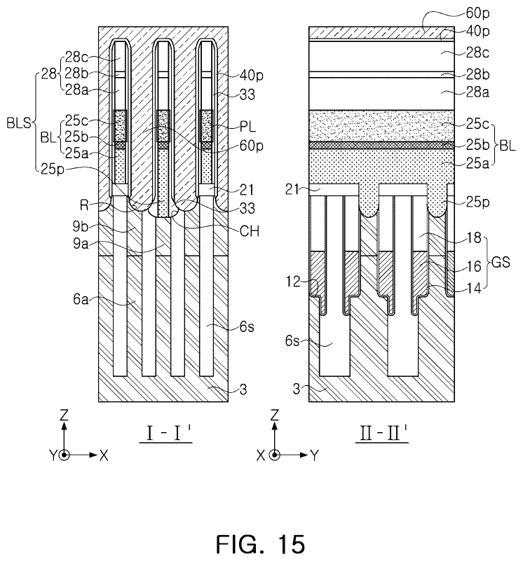

Referring to FIG. 15, a conductive layer 60p may be formed. First, the spacer material layer 40p may be etched between the bit line structures BLS to expose the second impurity region 9b and the device isolation layer 6s. By performing a wet etching process, the exposed second impurity region 9b may be etched, and a recess region R may be formed on the substrate 3. A conductive layer 60p may be formed to fill the recess region R. The conductive layer 60p may also be on (e.g., may completely cover) the spacer material layer 40p.

If a spacer on (e.g., covering) the bit line contact 25p includes a material such as silicon nitride, a natural oxide film formed on silicon nitride may be removed by the wet etching process. Accordingly, the conductive layer 60p formed later may include a protrusion, and there may be a risk that electrical characteristics of the contact plug 60 may be deteriorated. However, according to some example embodiments of the present disclosure, since the first spacer 33 on (e.g., covering) the bit line contact 25p includes at least one of SiOC or SiOCN, the first spacer 33 may not be etched by the wet etching process. Accordingly, the electrical characteristics of the contact plug 60 may be prevented from being deteriorated.

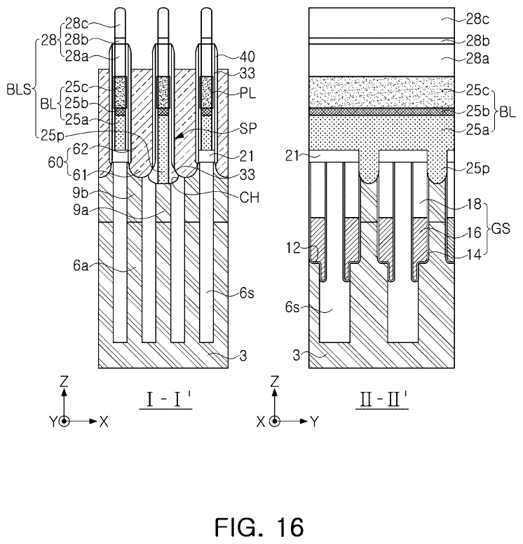

Referring to FIG. 16, the conductive layer 60p may be etched back to form a contact plug 60. An upper surface of the contact plug 60 may be disposed on a level lower than that of an upper end of the bit line structure BLS. The contact plug 60 may be in contact with an upper surface of the second impurity region 9b of the active region 6a. Then, upper portions of the first spacer 33 and the spacer material layer 40p may be etched by an etching process, and the bit line capping layer 28 may be exposed. The spacer material layer 40p may be etched to be on (e.g., to cover) the first spacer 33 to form an external spacer 40 disposed on the side surface of the bit line structures BLS. The first spacer 33, the protective layer PL, and the external spacer 40 may form a spacer structure SP.

In some example embodiments, the fence structure 63 illustrated in FIG. 1 may be formed after the contact plug 60 is formed. The fence structure 63 may be formed by removing a portion of the contact plug 60 and then filling a space in which a portion of the contact plug 60 was removed, with an insulating material. The fence structures may be formed between the bit line structures BLS to overlap the gate structure GS in the vertical direction (e.g., the Z-direction). The fence structures may be spaced apart from each other in the X-direction and the Y-direction. For example, the contact plugs 60 may be alternately arranged with the fence structures 63 in the Y-direction, between the bit line structures BLS (e.g., see FIG. 1). In other example embodiments, a process of forming the fence structure 63 may be performed before a process of forming the contact plug 60.

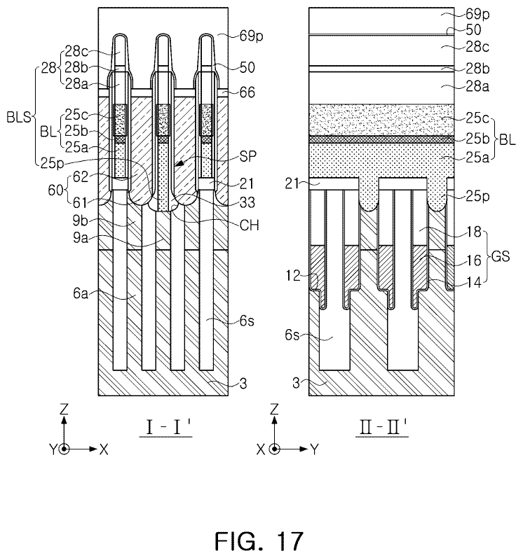

Referring to FIG. 17, a metal-semiconductor compound layer 66 and a conductive layer 69b may be formed. The metal-semiconductor compound layer 66 may be formed by converting a portion of the contact plug 60 into silicide or depositing a metal silicide layer on the contact plug 60. The conductive layer 69b may be on (e.g., may cover) the metal-semiconductor compound layer 66 and the bit line structures BLS.

In some example embodiments, after the metal-semiconductor compound layer 66 is formed, an upper insulating spacer 50 may be formed. The upper insulating spacer 50 may be on (e.g., may cover) an upper portion of the bit line structures BLS and may be covered with the conductive layer 69b.

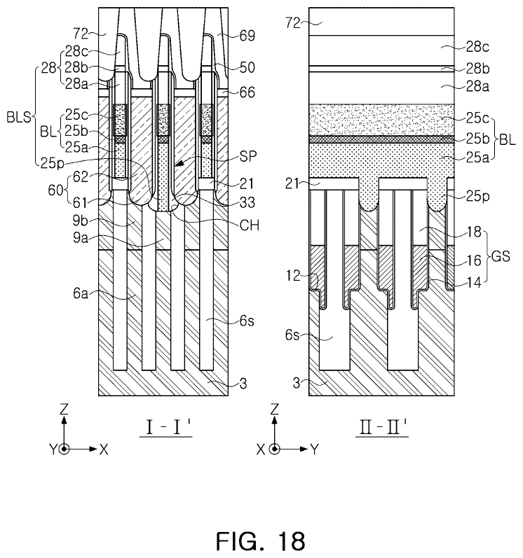

Referring to FIG. 18, a landing pad 69 may be formed by patterning the conductive layer 69b. An insulating material may be formed to be on (e.g., to cover) the landing pad 69 and the insulating material may be flattened to expose an upper surface of the landing pad 69 to form an insulating pattern 72. The landing pad 69 may be electrically connected to the second impurity region 9b through the contact plug 60. The landing pads 69 may be spatially separated from each other and electrically insulated from each other by the insulating patterns 72.

Referring back to FIG. 2, the etch stop layer 75 and the capacitor structure 80 may be formed on the landing pad 69 and the insulating pattern 72, thus manufacturing the semiconductor device 100. The etch stop layer 75 may be formed to be on (e.g., to cover) upper surfaces of the landing pad 69 and the insulating pattern 72. The capacitor structure 80 may include a lower electrode 82 connected to the landing pad 69 by penetrating through the etch stop layer 75, a capacitor dielectric layer 84 on the lower electrode 82, and an upper electrode 86 on the capacitor dielectric layer 84. As used herein, “an element A connected to an element B” (or similar language) means that the element A is physically and/or electrically connected to the element B.

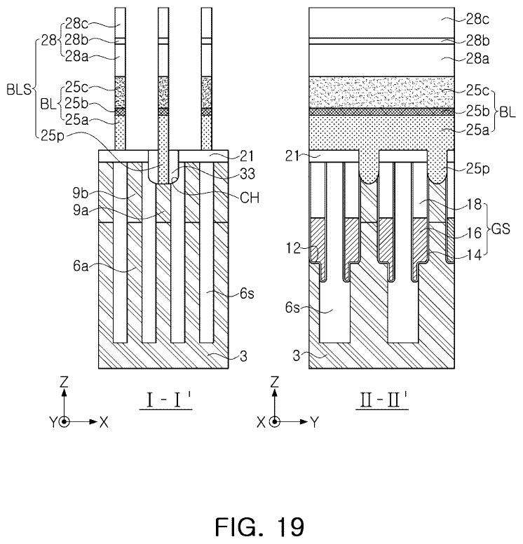

FIGS. 19 to 21 are vertical cross-sectional views illustrating a method of manufacturing a semiconductor device according to some example embodiments. For conciseness, an element previously described with reference to FIGS. 8 to 18 may be identified by the same reference number and a description thereof may be brief or omitted to avoid repeated descriptions.

Referring to FIG. 19, after the process of forming the first spacer material layer 33p described with reference to FIG. 12, the first spacer material layer 33p may be etched so that the bit line BL and the bit line capping layer 28 are exposed. For example, the etching process may include a wet etching process. The first spacer material layer 33p may be etched to form a first spacer 33 that comes into contact with a side surface of the bit line contact 25p and fills the contact hole CH.

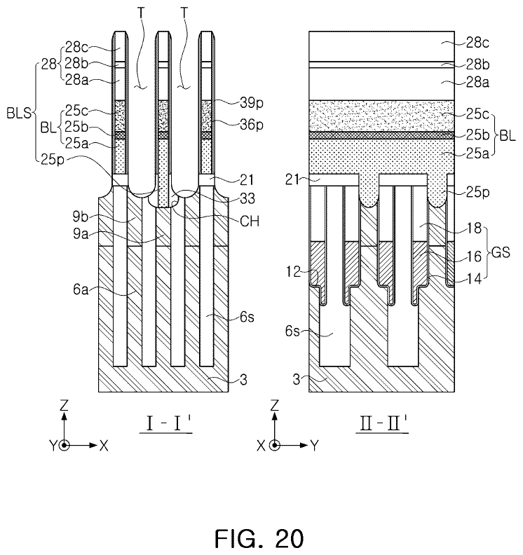

Referring to FIG. 20, a second spacer material layer 36p and a third spacer material layer 39p may be formed. First, the second spacer material layer 36p and the third spacer material layer 39p may be sequentially stacked to be on (e.g., to cover) a buffer layer 21 and bit line structures BLS. Then, an etching process may be performed to form trenches T extending in the Y-direction between the bit line structures BLS. The trench T may expose a side surface of the buffer layer 21, a second impurity region 9b, and an upper surface of a device isolation layer 6s. The second spacer material layer 36p and the third spacer material layer 39p may extend in the Y-direction along the side surface of the bit line structure BLS. Additionally, an upper surface of the third insulating layer 28c may be exposed through the etching process.

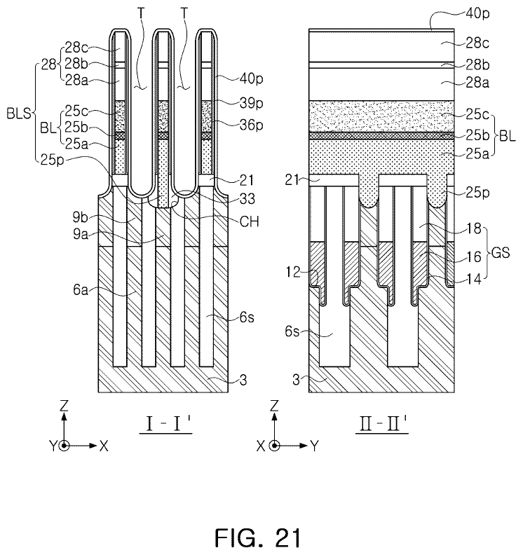

Referring to FIG. 21, a spacer material layer 40p may be formed. The spacer material layer 40p may be on (e.g., may cover) an internal wall of the trench T. For example, the spacer material layer 40p may be on (e.g., may cover) the side surface of the buffer layer 21, the second impurity region 9b, and the upper surface of the device isolation layer 6s, and may be on (e.g., may cover) the third spacer material layer 39p.

Then, the process described with reference to FIGS. 15 to 18 may be performed, and as illustrated in FIG. 6, the semiconductor device 100c including the first spacer 33, the second spacer 36, and the third spacer 39 may be manufactured.

The present disclosure is not limited to the above-described embodiments and the accompanying drawings but is defined by the appended claims. Therefore, those of ordinary skill in the art may make various replacements, modifications, or changes without departing from the scope of the present disclosure defined by the appended claims, and these replacements, modifications, or changes should be construed as being included in the scope of the present disclosure.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof. In addition, it will be understood that, although the terms “first”, “second”, etc. may be used herein to describe various elements, these elements should not be limited by these terms. Rather, these terms are only used to distinguish one element from another. For example, a first element could be termed a second element, and, similarly, a second element could be termed a first element, without departing from the scope of the present disclosure.

What is claimed is:

1. A semiconductor device, comprising:
a substrate that includes an active region comprising a first impurity region and a second impurity region, the substrate further including a contact hole that overlaps an upper surface of the first impurity region;
a gate structure in the substrate and intersecting the active region;
a bit line structure intersecting the gate structure, the bit line structure including a bit line contact in the contact hole and in contact with the first impurity region and a bit line on the bit line contact;
a spacer structure including an internal spacer on a side surface of the bit line structure and an external spacer on the internal spacer; and
a contact plug in contact with a first side surface of the external spacer and electrically connected to the second impurity region,
wherein the internal spacer is in the contact hole and includes a first spacer in contact with a second side surface of the external spacer opposite to the first side surface, and
wherein the first spacer includes a different material from the external spacer.

2. The semiconductor device of claim 1, wherein the first spacer includes a material having a lower tensile stress than a material included in the external spacer.

3. The semiconductor device of claim 2, wherein the external spacer includes silicon nitride, and
wherein the first spacer includes at least one of silicon oxycarbide or silicon oxycarbonitride.

4. The semiconductor device of claim 1, wherein the first spacer is in contact with a side surface of the bit line contact.

5. The semiconductor device of claim 1, wherein the internal spacer further includes a protective layer on a side surface of the bit line.

6. The semiconductor device of claim 5, wherein the protective layer includes at least one of silicon or silicon oxide.

7. The semiconductor device of claim 5, wherein the bit line includes a first conductive layer, a second conductive layer, and a third conductive layer, with the second conductive layer between the first conductive layer and the third conductive layer,
wherein the third conductive layer includes tungsten, and
wherein a side surface of the third conductive layer is in contact with the protective layer.

8. The semiconductor device of claim 1, wherein the first spacer includes a lower portion in contact with a side surface of the bit line contact and an upper portion in contact with a side surface of the bit line.

9. The semiconductor device of claim 8, wherein the upper portion includes a first portion spaced apart from the side surface of the bit line and a second portion in contact with the side surface of the bit line, and
wherein a horizontal width of the first portion of the upper portion is smaller than a horizontal width of the second portion of the upper portion.

10. The semiconductor device of claim 1, wherein a maximum horizontal width of the first spacer is wider than a horizontal width of a portion of the internal spacer on the bit line.

11. The semiconductor device of claim 1, wherein the internal spacer further includes a liner between the first spacer and the substrate, and
wherein the liner extends along the bit line contact and an internal wall of the contact hole.

12. The semiconductor device of claim 11, wherein the liner includes silicon oxide.

13. The semiconductor device of claim 1, wherein the internal spacer further includes:
a second spacer on the first spacer and on a side surface of the bit line; and
a third spacer between the second spacer and the external spacer.

14. A semiconductor device, comprising:
a substrate that includes an active region comprising a first impurity region and a second impurity region, the substrate further including a contact hole that vertically overlaps an upper surface of the first impurity region;
a gate structure in the substrate and intersecting the active region;
a buffer layer on the substrate;
a bit line structure intersecting the gate structure, the bit line structure including a bit line contact in the contact hole and in contact with the first impurity region and a bit line on the bit line contact;
a spacer structure including an internal spacer on a side surface of the bit line structure and an external spacer on the internal spacer; and
a contact plug in contact with a first side surface of the external spacer and electrically connected to the second impurity region,
wherein the internal spacer is in the contact hole and includes a first spacer in contact with a second side surface of the external spacer opposite to the first side surface,
wherein the first spacer includes a first portion that is closer to a lower surface of the substrate than a lower surface of the buffer layer is, and a second portion that horizontally overlaps the buffer layer, and
wherein a maximum horizontal width of the first portion of the first spacer is wider than a horizontal width of the second portion of the first spacer.

15. The semiconductor device of claim 14, wherein the substrate further includes a recess region that vertically overlaps an upper surface of the second impurity region,
wherein the contact plug includes a lower portion in the recess region and an upper portion on the lower portion and in contact with the external spacer, and
wherein the first portion of the first spacer is in contact with the lower portion of the contact plug.

16. The semiconductor device of claim 14, wherein the second portion of the first spacer is spaced apart from the contact plug.

17. The semiconductor device of claim 14, wherein the external spacer is on the first portion of the first spacer and is in contact with a side surface of the second portion of the first spacer.

18. The semiconductor device of claim 14, wherein a lower end of the external spacer is closer to the lower surface of the substrate than an upper surface of the substrate is.

19. The semiconductor device of claim 14, wherein the external spacer includes silicon nitride, and
wherein the first spacer includes at least one of silicon oxycarbide or silicon oxycarbonitride.

20. A semiconductor device, comprising:
a substrate that includes an active region comprising a first impurity region and a second impurity region, the substrate further including a contact hole that overlaps the first impurity region and a recess region that overlaps the second impurity region;
a gate structure in the substrate and intersecting the active region;
bit line structures intersecting the gate structure, at least one of the bit line structures including a bit line contact in the contact hole and in contact with the first impurity region and a bit line on the bit line contact;
spacer structures each including an internal spacer on a side surface of a respective one of the bit line structures and an external spacer on the internal spacer;
a contact plug between ones of the spacer structures and electrically connected to the second impurity region;
a landing pad on the contact plug; and
a capacitor structure on the landing pad,
wherein the internal spacer is in the contact hole and includes a first spacer in contact with a side surface of the external spacer,
wherein the external spacer includes silicon nitride, and
wherein the first spacer includes at least one of silicon oxycarbide or silicon oxycarbonitride.
